(19) United States
(12) Patent Application Publication
(10) Pub. No.: US 2024/0302758 A1
(43) Pub. Date: Sep. 12, 2024

(54) PATTERN CORRECTION DEVICE, PATTERN CORRECTION METHOD, AND PATTERN FORMATION METHOD FOR SEMICONDUCTOR DEVICES

(71) Applicant: Samsung Electronics Co., Ltd., Suwon-si (KR)

(72) Inventors: Ingyun CHUNG, Suwon-si (KR); Dongjin PARK, Suwon-si (KR); Sungyong MOON, Suwon-si (KR); Junyoung JANG, Suwon-si (KR)

(73) Assignee: Samsung Electronics Co., Ltd., Suwon-si (KR)

(21) Appl. No.: 18/411,581

(22) Filed: Jan. 12, 2024

(30) Foreign Application Priority Data
Mar. 10, 2023 (KR) 10-2023-0031883

(51) Int. Cl. G03F 9/00

(52) U.S. Cl. CPC G03F 9/7046; G03F 9/7049; G03F 9/7088; G03F 9/7092

(57) ABSTRACT

A pattern correction method includes acquiring, from a database, full shot data including full shot data coordinates and a misalignment value, calculating a deformation coefficient of the full shot data based on a cantilever beam analysis method with respect to the full shot data, extracting first-coordinate data along a first axis in a bit line direction and second-coordinate data along a second axis in a word line direction based on the full shot data, classifying the full shot data based on the first-coordinate data and the second-coordinate data, removing outliers from the full shot data.

### CROSS-REFERENCE TO RELATED APPLICATION

This application is based on and claims priority under 35 U.S.C. § 119 to Korean Patent Application No. 10-2023-0031883, filed on Mar. 10, 2023, in the Korean Intellectual Property Office, the disclosures of which are incorporated by reference herein in their entirety.

### BACKGROUND

The inventive concepts relate to a pattern correction device, a pattern correction method, and a pattern formation method for semiconductor devices.

Recently, as the integration of memory products accelerates along with the rapid development of process techniques for fine semiconductor devices, the area and operating voltage of unit cells have been markedly decreased. For example, although the area of semiconductor devices such as dynamic random access memory (DRAM) has been decreased as the degree of integration of semiconductor devices has been increased, semiconductor devices need to have the same or greater capacitance. An increase in the required capacitance leads to an increase in the aspect ratio of cylindrical lower electrodes. Therefore, cylindrical lower electrodes frequently lean or break before a dielectric material is deposited.

### SUMMARY

The inventive concepts provide a pattern correction device, a pattern correction method, and a pattern formation method for predicting the leaning of lower electrode patterns of semiconductor devices and precisely correcting support structure patterns of the semiconductor devices.

The inventive concepts are not limited to those mentioned above, and the inventive concepts will be apparently understood by those skilled in the art through the following description.

According to an aspect of the inventive concepts, there is provided a pattern correction method. The pattern correction method includes acquiring, from a database, full shot data including full shot data coordinates and a misalignment value, determining a deformation coefficient of the full shot data based on a cantilever beam analysis with respect to the full shot data, extracting first-coordinate data along a first axis in a bit line direction and second-coordinate data along a second axis in a word line direction based on the full shot data, classifying the full shot data based on the extracted first-coordinate data and the extracted second-coordinate data, training a pattern prediction model to predict misalignment values based on the first-coordinate data and the second-coordinate data by setting a predicted misalignment value as an output value, and setting the first-coordinate data, the second-coordinate data, the misalignment value, and the deformation coefficient of the full shot data as input values, acquiring target full shot data from the database, extracting a feature vector from the target full shot data using the pattern prediction model with respect to the target full shot data, detecting a target misalignment value of the target full shot data based on the feature vector, and determining a correction value for the target full shot data based on the predicted misalignment value of the target full shot data.

According to another aspect of the inventive concepts, there is provided a pattern correction method. The pattern correction method includes acquiring, from a database, full shot data including full shot coordinates and a misalignment value, determining a deformation coefficient of the full shot data based on a cantilever beam analysis with respect to the full shot data, extracting first-coordinate data along a first axis in a bit line direction and second-coordinate data along a second axis in a word line direction based on the full shot data, classifying the full shot data based on the extracted first-coordinate data and the extracted second-coordinate data, removing outliers from the full shot data, training a pattern prediction model to predict misalignment values based on the first-coordinate data and the second-coordinate data, the training based on regression learning using a Gaussian process and includes setting a predicted misalignment value as an output value, and setting the first-coordinate data, the second-coordinate data, the misalignment value, and the deformation coefficient of the full shot data as input values, acquiring target full shot data from the database, extracting a feature vector from the target full shot data using the pattern prediction model with respect to the target full shot data; detecting a target misalignment value of the target full shot data based on the feature vector; and calculating a correction value for the full shot data based on the target misalignment value. The deformation coefficient includes a first deformation coefficient with respect to the first axis in the bit line direction and a second deformation coefficient with respect to the second axis in the word line direction.

According to another aspect of the inventive concepts, there is provided a pattern correction method. The pattern correction method includes acquiring, from a database, full shot data including full shot coordinates and a misalignment value, determining a deformation coefficient of the full shot data based on a cantilever beam analysis method with respect to the full shot data, extracting first-coordinate data along a first axis in a bit line direction and second-coordinate data along a second axis in a word line direction based on the full shot data, classifying the full shot data based on the extracted first-coordinate data and the extracted second-coordinate data, removing outliers from the full shot data, to predict misalignment values based on the first-coordinate data and the second-coordinate data, the training based on regression learning using a Gaussian process and includes setting a predicted misalignment value as an output value, and setting the first-coordinate data, the second-coordinate data, the misalignment value, and the deformation coefficient of the full shot data as input values, acquiring target full shot data from the database, extracting a feature vector from the target full shot data using the pattern prediction model with respect to the target full shot data; detecting a target misalignment value of the target full shot data based on the feature vector, and calculating a correction value for the full shot data based on the target misalignment value. The determining of the deformation coefficient of the full shot data includes calculating a ratio between a lower electrode, a first support structure pattern, and a second support structure pattern based on a load acting on the lower electrode, a reaction force of the first support structure pattern, and a reaction force of the second support structure pattern, and determining the deformation coefficient for each of a plurality of unit blocks based on the ratio. The deformation coefficient includes a first deformation coefficient with respect to the first axis in the bit line direction and a second deformation coefficient with respect to the second axis in the word line direction.

### BRIEF DESCRIPTION OF THE DRAWINGS

Embodiments will be more clearly understood from the following detailed description taken in conjunction with the accompanying drawings in which:

FIG. 1 is a block diagram illustrating a pattern correction device according to at least one embodiment;

FIG. 2 is a diagram illustrating correction regions by a pattern correction device and a pattern correction method according to at least one embodiment;

FIG. 3 is a flowchart illustrating a pattern correction method according to at least one embodiment;

FIGS. 4A to 4C are diagrams illustrating a pattern leaning phenomenon and a method of calculating a deformation coefficient of a semiconductor device according to at least one embodiment;

FIG. 5 is a diagram illustrating unit blocks to be corrected by using a pattern correction device and a pattern correction method according to at least one embodiment;

FIG. 6 is a diagram illustrating full shot data to be corrected by using a pattern correction device and a pattern correction method according to at least one embodiment;

FIGS. 7A and 7B are diagrams illustrating a coordinate extraction method used by a pattern correction device and a pattern correction method according to at least one embodiment;

FIGS. 8A to 8C are diagrams illustrating a data clustering method used by a pattern correction device and a pattern correction method according to at least one embodiment;

FIGS. 9A to 9C are diagrams illustrating a method of removing outliers by using a pattern correction device and a pattern correction method according to at least one embodiment;

FIGS. 10A and 10B are diagrams illustrating data predicted by using a pattern correction device and a pattern correction method according to at least one embodiment; and

FIGS. 11A and 11B are diagrams illustrating data corrected by using a pattern correction device and a pattern correction method according to at least one embodiment.

### DETAILED DESCRIPTION OF THE EMBODIMENTS

Hereinafter, embodiments will be described with reference to the accompanying drawings. In the drawings, like reference numerals refer to like elements, and repeated descriptions thereof are omitted. When the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric.

In the following description, any of the elements and/or functional blocks disclosed, including those including “unit”, “ . . . er/or,” “module”, etc., may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

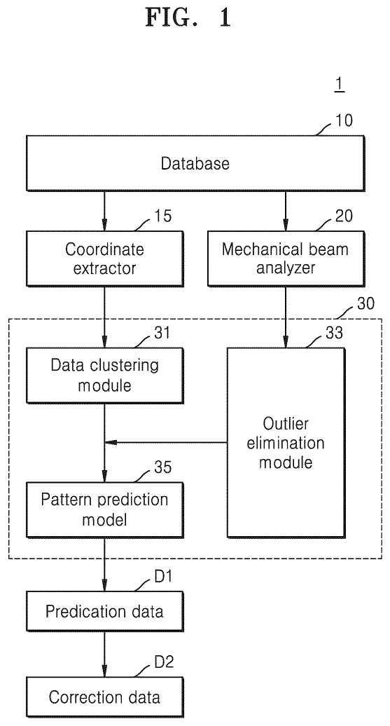

FIG. 1 is a block diagram illustrating a pattern correction device 1 according to at least one embodiment.

Referring to FIG. 1, the pattern correction device 1 may include a database 10, a coordinate extractor 15, a mechanical beam analyzer 20, and a pattern prediction module 30. The pattern prediction module 30 may include a data clustering module 31, an outlier elimination module 33, and a pattern prediction model 35.

The database 10 is configured to store target full shot data and full shot data that are received from a server (not shown). The target full shot data and the full shot data may each include location information on lower electrodes, location information on a support structure, a misalignment value of the support structure with respect to the lower electrodes, size information on unit blocks, and/or the like (described below). The misalignment value may indicate a degree of misalignment of the support structure with respect to the lower electrodes. In addition, the misalignment value may be a value measured from a semiconductor device including the lower electrodes and the support structure. Here, the database 10 may have a general data structure implemented in a storage space (for example, a hard disk or memory) of a computer system using a database management system (DBMS). For example, in at least one embodiment, the storage space may be (or be included in) a non-transitory computer readable media. The term “non-transitory,” as used herein, is a description of the medium itself (e.g., as tangible, and not a signal) as opposed to a limitation on data storage persistency (e.g., RAM vs. ROM). For example, the computer-readable recording medium may be any tangible medium that can store or include the program in or connected to an instruction execution system, equipment, or device. The database 10 may be provided in the form of a data storage in which data search, deletion, edition, addition, or the like may be freely performed. The database 10 may be implemented according to embodiments by using: a relational database management system (RDBMS) such as Oracle, Informix, Sybase, or DB2; an object-oriented database management system (OODBMS) such as Gemstone or Orion; and an XML native database such as Excelon, Tamino, or Sekaiju, and/or the like. The database 10 may have fields or elements to implement functions thereof. In addition, the database 10 may transmit and receive data such as full shot data and target full shot data to and from the coordinate extractor 15, the mechanical beam analyzer 20, and the pattern prediction module 30.

The coordinate extractor 15 is configured to extract first-coordinate data along a first axis in a bit line direction from full shot data received from the database 10. In addition, the coordinate extractor 15 may extract second-coordinate data along a second axis in a word line direction. The coordinate extractor 15 may transmit coordinate information about the extracted first-coordinate data and the extracted second-coordinate data to the pattern prediction module 30 together with the full shot data. In addition, the coordinate extractor 15 may transmit the coordinate information and the full shot data to the mechanical beam analyzer 20. In addition, according to at least some embodiments, the coordinate extractor 15 may receive data from the mechanical beam analyzer 20, extract coordinates from the received data (for example, first-coordinate data information for the first axis and second-coordinate data information for the second axis), and transmit extracted coordinate information (for example, the first-coordinate data information and the second-coordinate data information) and the received data to the mechanical beam analyzer 20.

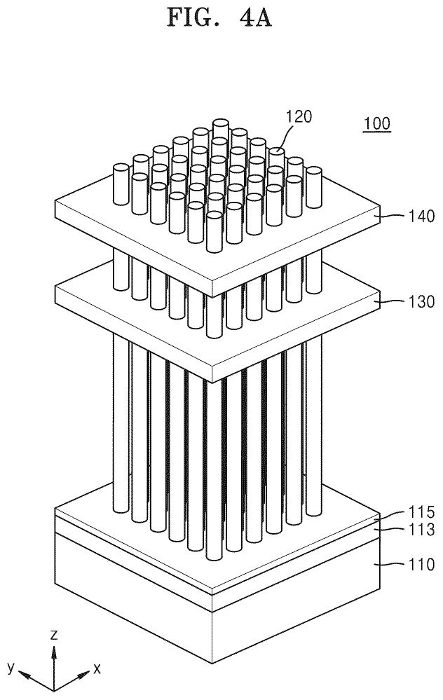

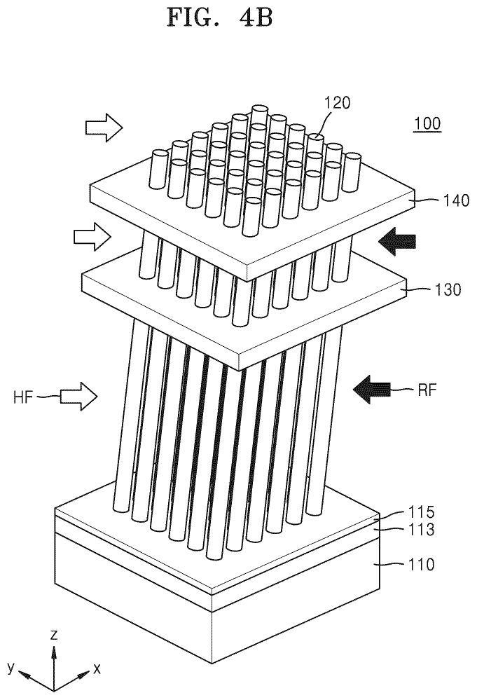

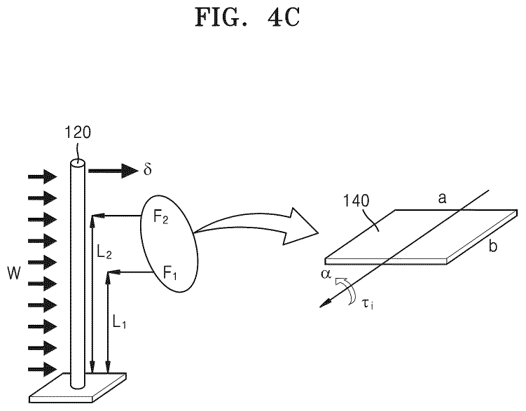

The mechanical beam analyzer 20 is configured to calculate a deformation coefficient of the full shot data based on a cantilever beam analysis method with respect to the full shot data. The deformation coefficient may have different values according to the sizes of the unit blocks. The deformation coefficient may include a stress coefficient and may refer to the degree to which the lower electrodes of the semiconductor device are deformed by external force. A method of calculating the deformation coefficient is described later with reference to FIGS. 4A to 4C. The mechanical beam analyzer 20 may match the calculated deformation coefficient with the full shot data received from the database 10 and may transmit, to the pattern prediction module 30, the full shot data to which the deformation coefficient is matched.

The data clustering module 31 is configured to perform data clustering. For example, the data clustering module 31 may classify the full shot data based on the coordinate information on the first-coordinate data and the second-coordinate data received from the coordinate extractor 15. For example, the data clustering module 31 may differentiate the coordinate information on the first-coordinate data and the second-coordinate data. The data clustering module 31 may calculate a differential value of the first-coordinate data based on Equation 1 below.

$$f {X}_{i + 1} - f {X}_{i} = {dX}_{i} \qquad [ Equation 1 ]$$

In Equation 1 above, fXᵢ₊₁ may refer to an (i+1)th first-coordinate data value, fXᵢ may refer to an ith first-coordinate data value, and dXᵢ may refer to a differential value of the ith first-coordinate data value. i may refer to a natural number ranging from 1 to n. The first-coordinate data may include first to n-th first-coordinate data values.

In addition, the data clustering module 31 may calculate a differential value of the second-coordinate data based on Equation 2 below.

$${fY}_{i + 1} - {fY}_{i} = {dY}_{i} \qquad [ Equation 2 ]$$

In Equation 2 above, fYᵢ₊₁ may refer to an (i+1)th second-coordinate data value, fYᵢ may refer to an ith second-coordinate data value, and dYᵢ may refer to a differential value of the ith second-coordinate data value. i may refer to a natural number ranging from 1 to n. The second-coordinate data may include first to nth second-coordinate data values.

Next, the data clustering module 31 is configured to classify the full shot data based on differential values of the first-coordinate data and differential values of the second-coordinate data. For example, the data clustering module 31 may classify the full shot data to generate full shot data for the first axis and full shot data for the second axis. The data clustering module 31 may classify the full shot data in units of shots and chips.

The outlier elimination module 33 is configured to remove outliers from the full shot data received from the mechanical beam analyzer 20. The outlier elimination module 33 may remove outliers from the full shot data based on an isolation forest algorithm. Outliers refer to abnormal extreme values or unrealistic variable values compared to the distribution of other values in the full shot data. The outlier elimination module 33 may transmit corrected full shot data obtained by removing outliers from the full shot data. Here, the corrected full shot data may refer to full shot data from which outliers are removed.

The pattern prediction model 35 is configured to learn a misalignment value caused by pattern leaning, based on the coordinate information received from the data clustering module 31 and the full shot data received from the outlier elimination module 33. For example, the computing device 100 may have a structure that is trainable, e.g., with training data, such as an artificial neural network, a decision tree, a support vector machine, a Bayesian network, a genetic algorithm, and/or the like. Non-limiting examples of the trainable structure may include a convolution neural network (CNN), a generative adversarial network (GAN), an artificial neural network (ANN), a region based convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, and/or the like. In at least one embodiment, the pattern prediction model 35 may learn by setting a predicted misalignment value as an output value, and the first-coordinate data, the second-coordinate data, the misalignment value, and the deformation coefficient of the full shot data as input values. Here, the pattern prediction model 35 may learn based on a regression learning method using a Gaussian process. In addition, the pattern prediction model 35 may acquire target full shot data from an external server or the database 10 and may detect a prediction misalignment value for the target full shot data. For example, the pattern prediction model 35 may extract a feature vector from the target full shot data and may detect a prediction misalignment value of the target full shot data based on the feature vector.

The pattern correction device 1 is configured to generate a predicted misalignment value D1 of the target pool shot data using the pattern prediction model 35 and may calculate a correction value for the target full shot data based on the predicted misalignment value D1 Here, the correction value for the target full shot data may refer to a position correction value for the support structure.

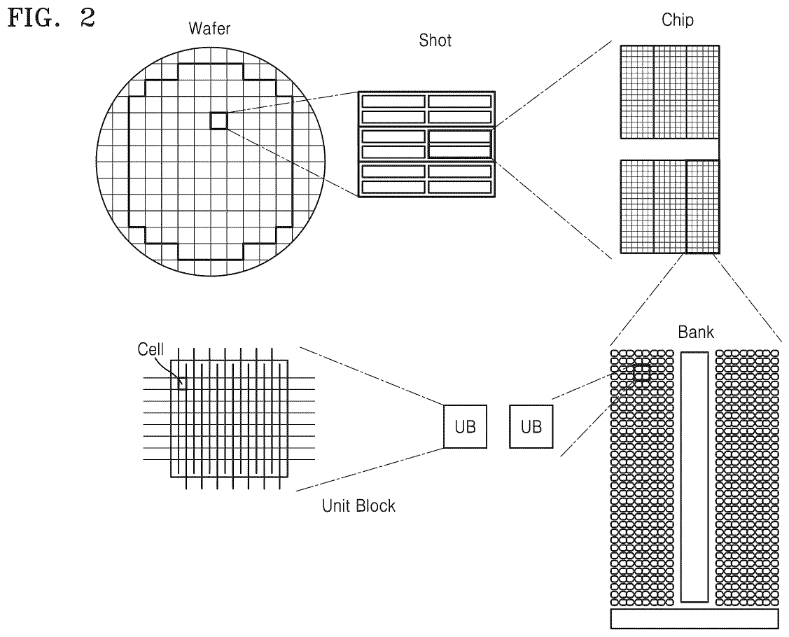

FIG. 2 is a diagram illustrating correction regions by the pattern correction device 1 and a pattern correction method according to at least one embodiment.

Referring to FIG. 2, the correction regions by the pattern correction device 1 and the pattern correction method are illustrated based on a wafer, a shot, a chip, a bank, a unit block, and a cell. Referring to FIG. 2, the wafer is shown at the top left, and a plurality of shots indicated by straight lines are shown inside the wafer. Herein, the term “shot” may refer to a process of transferring patterns from a mask to a wafer through one exposure in a lithography process and/or a region of the wafer corresponding to the process.

The second from the top left is an enlarged view of a shot, and a plurality of chips may be included in one shot. For example, in at least one example, twelve and/or eighteen chips may be included in one shot. However, the number of chips included in one shot is not limited thereto, and the number of chips may be more or less than twelve and/or eighteen. For example, a shot may include one chip or a plurality of chips depending on the type of chips.

The third from the top left is an enlarged view of a chip. In a chip, for example, a memory chip such as a dynamic random access memory (DRAM) chip, a plurality of banks may be arranged on both sides of a center scribe lane.

The first from the bottom right is an enlarged view of banks. Here, the term “bank” may refer to a collection of unit blocks. A scribe lane may also be provided between banks. For example, the term “scribe lane” may usually refer to a region configured to be sawed and/or divided. However, the term “scribe lane” may also refer to a region other than banks in which cells are arranged. A unit block is shown enlarged at the bottom leftmost corner. Herein, the term “unit block” may refer to a collection of cells. Here, the pattern correction device 1 may perform pattern correction on the entire wafer or in units of shots, chips, or blocks for the entire wafer. In addition, the pattern correction device 1 may correct patterns of support structures in units of full shots, chips, or blocks.

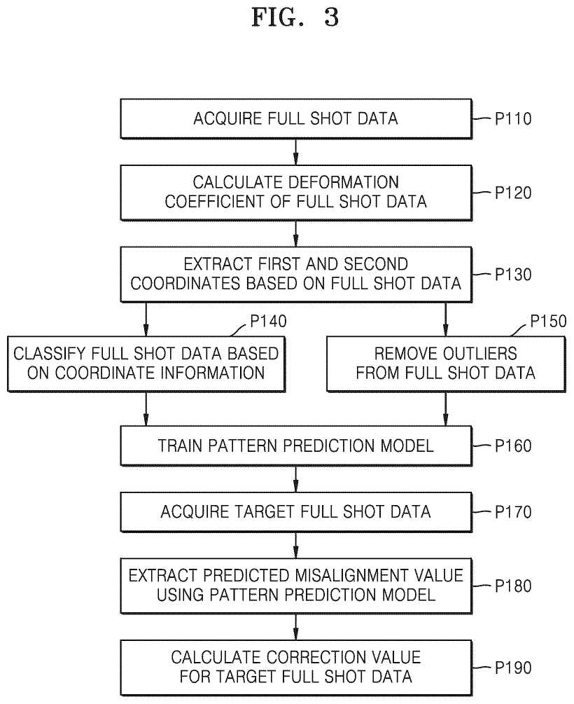

FIG. 3 is a flowchart illustrating a pattern correction method according to at least one embodiment.

Referring to FIG. 3, first, the pattern correction method of the embodiment may include acquiring full shot data containing full shot coordinates and a misalignment value from a database (operation P110). After acquiring the full shot data, a deformation coefficient of the full shot data may be calculated based on, e.g., a cantilever beam analysis method (operation P120). Based on the full shot data, first-coordinate data may be extracted along a first axis in a bit line direction, and second-coordinate data may be extracted along a second axis in a word line direction (operation P130).

Next, the full shot data may be classified based on the first-coordinate data and the second-coordinate data (operation P140). Outliers of the full shot data may be removed (operation P150). In at least one embodiment, operations P140 and P150 may be simultaneously performed in parallel after extracting the first-coordinate data and the second-coordinate data.

After performing operations P140 and P150, a pattern prediction model may be trained by setting a predicted misalignment value as an output value, and the first-coordinate data, the second-coordinate data, the misalignment value, and the deformation coefficient of the full shot data as input values (operation P160). Target full shot data may be acquired from the database (operation P170). A feature vector may be extracted from the target full shot data using the pattern prediction model with respect to the target full shot data, and a predicted misalignment value of the target full shot data may be detected based on the feature vector (operation P180). A correction value may be calculated for the target full shot data based on the detected predicted misalignment value (operation P190).

A specific method for each operation is described below with reference to the drawings.

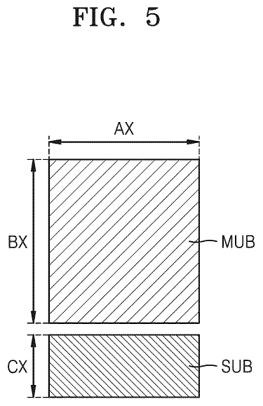

FIG. 4A to 4C are diagrams illustrating a pattern leaning phenomenon and a method of calculating a deformation coefficient of a semiconductor device according to at least one embodiment. FIG. 5 is a diagram illustrating unit blocks to be corrected by a pattern correction device and a pattern correction method according to at least one embodiment. Descriptions of FIGS. 4A to 4C and 5 will now be given with reference to FIGS. 1 and 3 together, and those described above with reference to FIGS. 1 to 3 will be briefly described or not be described.

Referring to FIGS. 4A and 4B, a semiconductor device 100 to be corrected by a pattern correction device and a pattern correction method is illustrated. The semiconductor device 100 may include a substrate 110, an interlayer insulating layer 113, an etch stop layer 115, a plurality of lower electrodes 120, a first support structure pattern 130, and a second support structure pattern 140. A dielectric layer (not shown) and an upper electrode may be formed on the first support structure pattern 130 and the second support structure pattern 140.

For example, the substrate 110 may include a semiconductor material such as silicon, germanium, and/or silicon-germanium, and may further include, in at least some embodiments, an epitaxial layer, a silicon-on-insulator (SOI) layer, a germanium-on-insulator (GOI) layer, a semiconductor-on-insulator (SeOI) layer, and/or the like. The substrate 110 may include a semiconductor substrate and/or semiconductor elements. For example, the semiconductor elements may include metal oxide semiconductor (MOS) transistors, diodes, and/or resistors. Gate lines and bit lines may be formed on the semiconductor substrate. The interlayer insulating layer 113 may include a high density plasma (HDP) oxide, tetraethyl orthosilicate (TEOS), plasma enhanced tetraethyl orthosilicate (PE-TEOS), o3-tetraethyl orthosilicate (O3-TEOS), undoped silicate glass (USG), phospho silicate glass (PSG), borosilicate glass (BSG), borophosphosilicate glass (BPSG), fluoride silicate glass (FSG), spin on glass (SOG), tonen silazene (TOSZ), a combination thereof, and/or the like. In addition, the interlayer insulating layer 113 may include an insulator material, such as silicon nitride, silicon oxynitride, or a material having a low permittivity such as a material having permittivity lower than that of silicon oxide. In at least one embodiment, the interlayer insulating layer 113 may be planarized before the deposition of the etch stop layer 115.

The etch stop layer 115 may include a material having etch selectivity with respect to the interlayer insulating layer 113. For example, the etch stop layer 115 may include a silicon nitride layer, a silicon oxynitride layer, and/or the like.

The lower electrodes 120 may include at least one conductive material, such as metal materials, metal nitride layers, and/or metal silicides. For example, the lower electrodes 120 may include a refractory metal material such as cobalt, titanium, nickel, tungsten, or molybdenum; a metal nitride layer such as a titanium nitride (TiN) layer, a titanium silicon nitride (TiSiN) layer, a titanium aluminum nitride (TiAlN) layer, a tantalum nitride (TaN) layer, a tantalum silicon nitride (TaSiN) layer, and a tantalum aluminum nitride (TaAlN) layer, or a tungsten nitride (WN) layer; and/or a layer of at least one noble metal selected from the group consisting of platinum (Pt), ruthenium (Ru), and iridium (Ir). In at least some embodiments, the lower electrodes 120 may include a conductive noble metal oxide layer.

The lower electrodes 120 may have a narrow long shape extending in a direction (2 direction) perpendicular to both a first direction (x direction) and a second direction (y direction) that are parallel to a main surface of the substrate 110. For example, the lower electrodes 120 may be referred to as extending perpendicularly from the main surface of the substrate 110. The lower electrodes 120 may be arranged in a plurality of rows and a plurality of columns in the first direction (x direction) and the second direction (y direction). In this case, lower electrodes 120 of one row may be staggered with respect to lower electrodes 120 of another row adjacent to the row to secure a space therebetween. For example, in at least one embodiment, the lower electrodes 120 may be referred to as being arranged in a non-array configuration. Because the lower electrodes 120 are staggered as described above, a relatively wide space may be secured between the lower electrodes 120, and thus a dielectric material may be easily deposited in a subsequent process such as a dielectric deposition process.

The lower electrodes 120 may have a pillar structure, and cross sections of the lower electrodes 120 may be circular or elliptical. However, the lower electrodes 120 are not limited thereto, and may have, e.g., a polygonal cross section.

In at least one embodiment, the aspect ratio of the lower electrodes 120 (that is, the height-to-width ratio of the lower electrodes 120) may be within a range of about 10 to about 35. Because the aspect ratio of the lower electrodes 120 is large as described above, the lower electrodes 120 may lean or break. Therefore, the semiconductor device 100 may further include the first support structure pattern 130 and the second support structure pattern 140 to reduce and/or prevent the leaning of the lower electrodes 120.

In this case, the first support structure pattern 130 and the second support structure pattern 140 may include an insulative nitride, but are not limited thereto. The semiconductor device 100 is illustrated as including two support structure patterns, that is, the first support structure pattern 130 and the second support structure pattern 140. However, the semiconductor device 100 is not limited thereto. For example, the semiconductor device 100 may include only the second support structure pattern 140 and/or may include additional support structure patterns depending on the aspect ratio of the lower electrodes 120.

The first support structure pattern 130 may be of a one-body type including a plurality of first open regions (not shown), and the second support structure pattern 140 may be of a one-body type including a plurality of second open regions (not shown). For example, each of the first support structure pattern 130 and the second support structure pattern 140 may have an entirely continuous structure. Each of the first support structure pattern 130 and the second support structure pattern 140 may have a flat plate shape that is parallel to the main surface of the substrate 110 and is at a height from the main surface of the substrate 110.

The first support structure pattern 130 may be formed at a lower level from the main surface of the substrate 110 than the second support structure pattern 140 is. Therefore, the first open regions and the second open regions may overlap each other in a direction perpendicular to the main surface of the substrate 110. In this case, the cross-sectional area of each of the first open regions may be less than the cross-sectional area of each of the second open regions. For example, the first support structure pattern 130 may be thinner than the second support structure pattern 140, e.g., in a direction parallel to a direction the lower electrodes 120 extend.

Here, it may be expressed that the lower electrodes 120 are open through the first open regions and through the second open regions open, and this expression is for describing the structures of the first support structure pattern 130 and the second support structure pattern 140 before a dielectric layer and an upper electrode are deposited. After the dielectric layer and the upper electrode are formed, the lower electrodes 120 are covered by the dielectric layer and the upper electrode, and thus the lower electrodes 120 may not be open through the first open regions and the second open regions. Therefore, the first open regions and the second open regions may be understood as regions in which the dielectric layer and the upper electrode are formed at levels of the first and second support structure patterns 130 and 140 from the main surface of the substrate 110 without being in contact with the first and second support structure patterns 130 and 140.

Here, the lower electrodes 120 of the semiconductor device 100 may lean by external force HF. In this case, the first support structure pattern 130 and the second support structure pattern 140 may be out of alignment with the lower electrodes 120, and this may be referred to as misalignment.

Referring to FIGS. 1, 3, 4B, and 4C, in operation P120, the mechanical beam analyzer 20 may calculate a deformation coefficient of the full shot data based on a cantilever beam analysis method. For example, the modulus of elasticity of the lower electrodes 120 may be referred to as E, the moment of inertia of the lower electrodes 120 may be referred to as I, and the deflection of each of the lower electrodes 120 may be referred to as 8, and the horizontal length and the vertical length of each of the first support structure pattern 130 and the second support structure pattern 140 may be referred to as “a” and “b”.

In this case, the mechanical beam analyzer 20 may calculate torque caused by the rotation of the first support structure pattern 130 and the second support structure pattern 140 using Equation 3 below.

$${τ}_{i} = I α = {L}_{i} \times {F}_{i} \qquad [ Equation 3 ]$$

In Equation 3 above, τᵢ refers to torque due to rotation of an ith support structure pattern, I refers to moment of inertia, and α refers to angular acceleration. Lᵢ refers to the vertical level of the ith support structure pattern, and Fᵢ refers to the reaction force RF of the ith support structure pattern. The ith support structure pattern may be any one of the first support structure pattern 130 and the second support structure pattern 140.

Next, the mechanical beam analyzer 20 may calculate the reaction force RF of the first support structure pattern 130 and the second support structure pattern 140 using Equation 4 below.

$${F}_{i} = \frac{I}{{L}_{i}} α = \frac{12 α}{ρ} \frac{{ab}^{3}}{{L}_{i}} = β \frac{a {b}^{3}}{{L}_{i}} \qquad [ Equation 4 ]$$

In Equation 4 above, I refers to moment of inertia, and a refers to angular acceleration. Lᵢ refers to the vertical level of the ith support structure pattern, and Fᵢ refers to the reaction force of the ith support structure pattern. The ith support structure pattern may be any one of the first support structure pattern 130 and the second support structure pattern 140. In addition, “a” may refer to the horizontal length of a unit block corresponding to a point of the ith support structure pattern, and “b” may refer to the vertical length of the unit block corresponding to the point of the ith support structure pattern.

The mechanical beam analyzer 20 may perform an operation as in Equation 5 below based on a cantilever beam analysis method.

$$\sum M = EI \ddot{δ} \qquad [ Equation 5 ]$$

$$EI \ddot{δ} = - \frac{1}{2} {w ( L - x )}^{2} + {F}_{1} ( {L}_{1} - x ) + {F}_{2} ( {L}_{2} - x )$$

$$δ = \frac{1}{EI} \text{} ( - \frac{1}{24} {w ( L - x )}^{4} - \text{} \frac{1}{6} ( {F}_{1} + {F}_{2} ) {x}^{3} + \frac{1}{2} ( {L}_{1} {F}_{1} + {L}_{2} {F}_{2} ) {x}^{2} - \frac{1}{6} w {L}^{3} x + \frac{1}{24} w {L}^{4} )$$

$${L}_{1} = \frac{1}{2} L , {L}_{2} = \frac{5}{6} L , x = 0 , δ = 0 , \dot{δ} = 0$$

$${δ}_{L} = \frac{{L}^{2}}{72 EI} ( - 7 w {L}^{2} + \frac{250}{9} α I )$$

In Equation 5 above, M may refer to the kinetic moment of a lower electrode.

Referring to FIGS. 4A to 5, through this, the mechanical beam analyzer 20 may calculate that the deformation of the lower electrodes 120 is inversely proportional to the moment of inertia I of each of the first support structure pattern 130 and the second support structure pattern 140. The mechanical beam analyzer 20 may calculate a deformation coefficient by considering the sizes of a main unit block MUB and a sub-unit block SUB. In some embodiments, when the main unit block MUB corresponds to the positions of the first support structure pattern 130 and the lower electrodes 120 to be calculated, the mechanical beam analyzer 20 may respectively substitute a horizontal length AX and a vertical length BX for “a” and “b” in Equation 4 above. Furthermore, in embodiments, when the sub-unit block SUB corresponds to the positions of the first support structure pattern 130 and the lower electrodes 120 to be calculated, the mechanical beam analyzer 20 may respectively substitute the horizontal length AX and a vertical length CX for “a” and “b” in Equation 4 above.

In this manner, the deflection δ of each of the lower electrodes 120 may be calculated by considering the sizes of unit blocks. In this case, the mechanical beam analyzer 20 may set the deformation coefficient of the main unit block MUB to be one (1) and calculate the deformation coefficient of each of unit blocks based on the ratio of the deflection of the unit block to the deflection of the main unit block MUB.

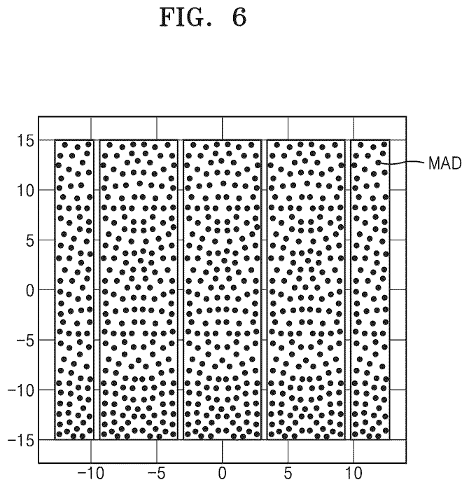

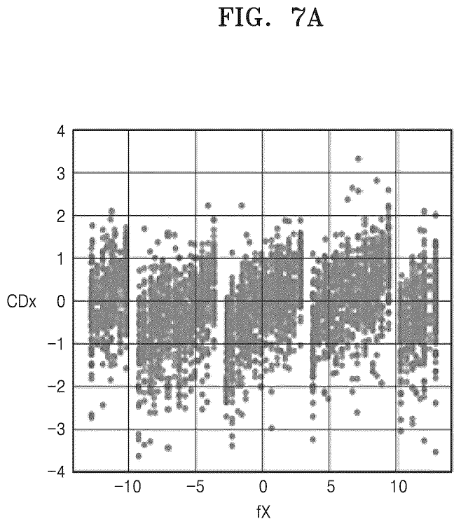

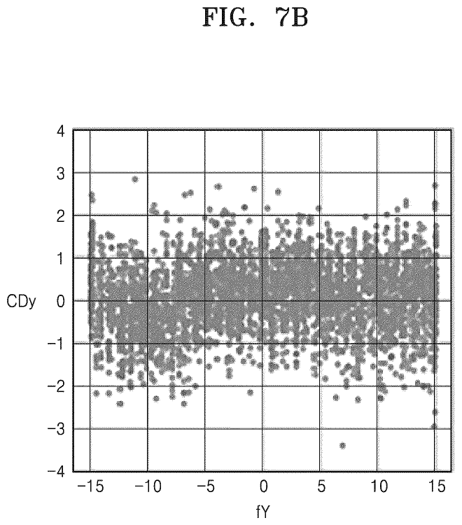

FIG. 6 is a diagram illustrating full shot data that is to be corrected by a pattern correction device and a pattern correction method according to at least one embodiment. FIGS. 7A and 7B are diagrams illustrating a coordinate extraction method used by a pattern correction device and a pattern correction method according to at least one embodiment. Descriptions of FIGS. 6, 7A, and 7B will now be given with reference to FIGS. 1 and 3 together, and those described above with reference to FIGS. 1 to 3 will be briefly described or not be described. Here, FIG. 7A shows first-coordinate data, and FIG. 7B shows second-coordinate data.

Referring to FIGS. 6, 7A, and 7B, in operation P130, the coordinate extractor 15 may extract, from full shot data received from the database 10, first-coordinate data in a first axis in a bit line direction and second-coordinate data along a second axis in a word line direction. The coordinate data may also be referred to as mean absolute deviation (MAD) data.

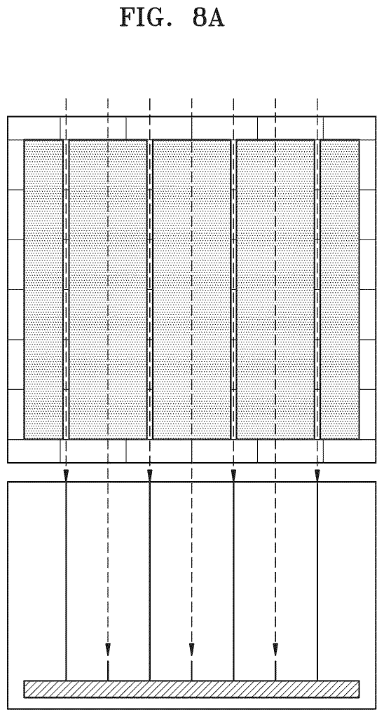

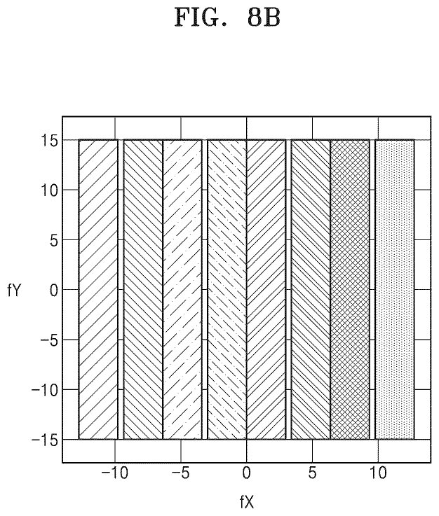

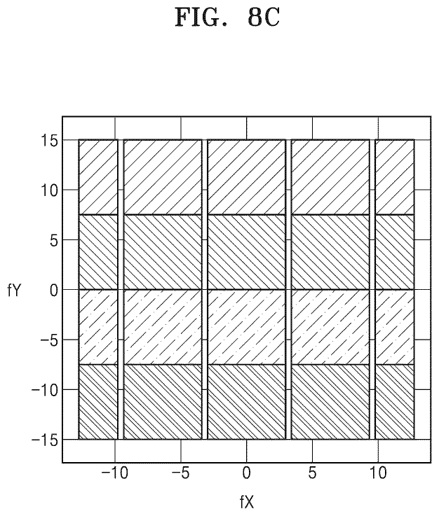

Referring to FIGS. 8A to 8C, in operation P140, the data clustering module 31 may classify the full shot data based on the first-coordinate data and the second-coordinate data. As described above with reference to FIG. 1, FIG. 8A shows an operation of differentiating and classifying the first-coordinate data and the second-coordinate data. FIG. 8B shows the first-coordinate data classified based on differential values of the first-coordinate data along the first axis, and FIG. 8C shows the second-coordinate data classified based on differential values of the second-coordinate data along the second axis.

Referring to FIGS. 8B and 8C, based on the differential values of the first-coordinate data and the differential values of the second-coordinate data, classification may be performed according to a plurality of shot regions of the first-coordinate data and the second-coordinate data. Different patterns in FIGS. 8B and 8C refer to the shot regions.

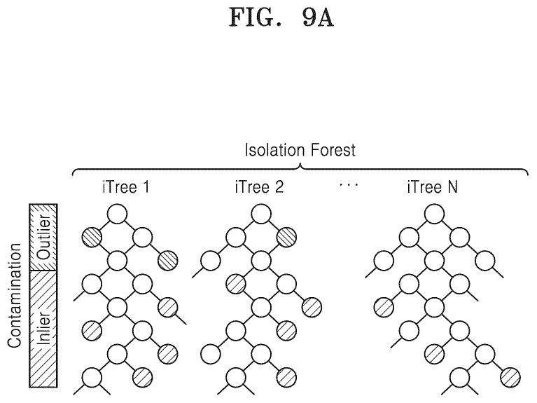

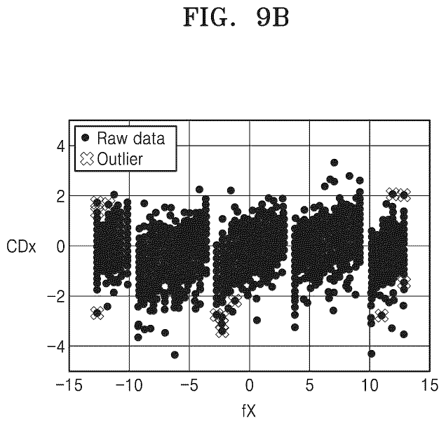

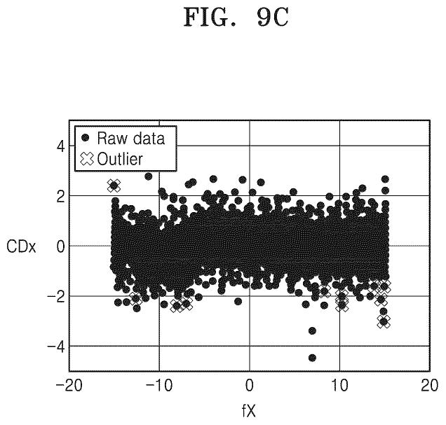

FIGS. 9A to 9C are diagrams illustrating a method of removing outliers using a pattern correction device and a pattern correction method according to at least one embodiment.

Referring to FIGS. 9A to 9C, in operation P150, the outlier elimination module 33 may remove outliers from the full shot data.

Referring to FIGS. 1 and 9A, the outlier elimination module 33 may remove outliers from the full shot data based on an isolation forest algorithm. For example, to find abnormal values showing patterns different from normal patterns (for example, inliers) in the full shot data, the isolation forest algorithm may express data sets in the form of decision trees, and goes down the decision trees in a depth direction when isolating inliers and goes to upper ends of the decision trees when isolating outliers. Using this, the outlier elimination module 33 may isolate inliers and outliers based on the number of times going down the decision trees at the time of isolation. In this manner, the outlier elimination module 33 may remove outliers from the full shot data.

For example, referring to FIGS. 1 and 9B, the outlier elimination module 33 may remove outliers from the first-coordinate data.

Referring to FIGS. 1 and 9C, the outlier elimination module 33 may remove outliers from second-coordinate data.

As described above, the outlier elimination module 33 may remove outliers from the first-coordinate data and outliers from the second-coordinate data, and operation P150 shown in FIG. 3 may include removing outliers from the first-coordinate data and outliers from the second coordinate.

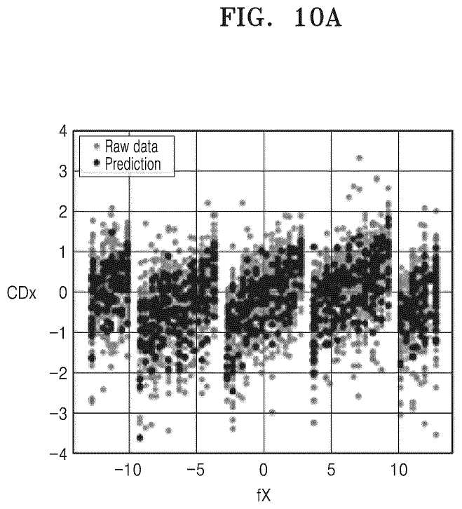

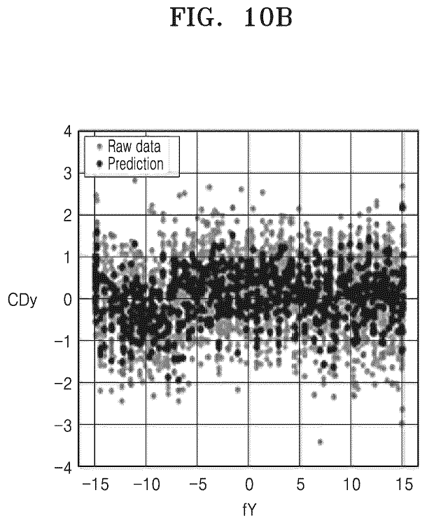

FIGS. 10A and 10B are diagrams illustrating data predicted by a pattern correction device and a pattern correction method according to at least one embodiment. Descriptions of FIGS. 10A and 10B will now be given with reference to FIGS. 1 and 3 together, and those described above with reference to FIGS. 1 to 3 will be briefly described or not be described.

Referring to FIGS. 1, 10A, and 10B, in operation P160, the pattern prediction model 35 may learn by setting a predicted misalignment value as an output value, and the first-coordinate data, the second-coordinate data, the misalignment value, and the deformation coefficient of the full shot data as input values. Next, in operation P170, the pattern prediction model 35 may acquire target full shot data from the database 10, extract a feature vector from the target full shot data, and detect a predicted misalignment value of the target full shot data based on the feature vector. The pattern prediction model 35 may classify the target full shot data in units of shots and chips based on the classified full shot data.

For the target full shot data (raw data in FIGS. 10A and 10B), the pattern prediction model 35 may generate first-target coordinate data along the first axis in the bit line direction and second-target coordinate data along the second axis in the word line direction. Here, the first-target coordinate data refers to points indicated by “prediction” in FIG. 10A, and the second-target coordinate data refers to points indicated by “prediction” in FIG. 10B. In this manner, the pattern prediction model 35 may predict and/or detect misalignment values along the first axis and the second axis with respect to the target full shot data.

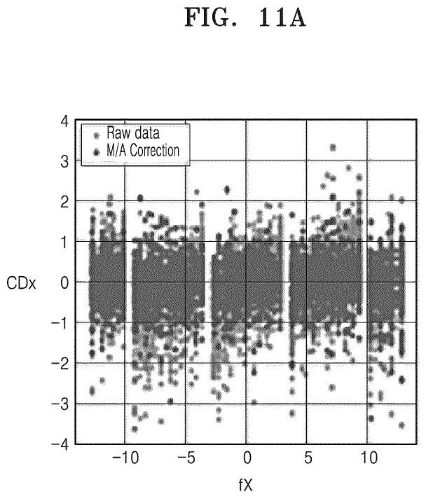

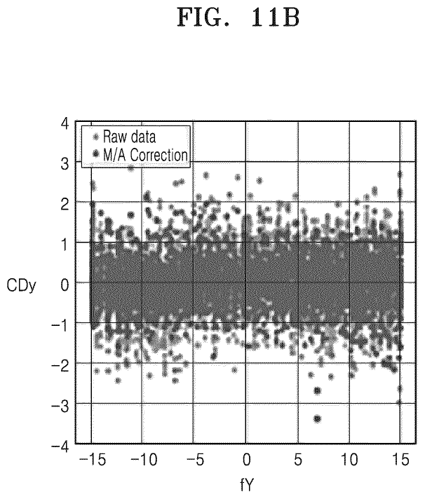

FIGS. 11A and 11B are diagrams illustrating data corrected by a pattern correction device and a pattern correction method according to at least one embodiment. Descriptions of FIGS. 11A and 11B will now be given with reference to FIGS. 1 and 3 together, and those described above with reference to FIGS. 1 to 3 will be briefly described or not be described.

Referring to FIGS. 11A and 11B, in operation P180, the pattern correction device 1 may calculate correction values for the target full shot data based on the misalignment values that are predicted by the pattern prediction model 35 along the first axis and the second axis with respect to the target full shot data. Here, the correction values for the target full shot data may refer to correction values for the first support structure pattern 130 and the second support structure pattern 140 shown in FIG. 4A. According to a pattern formation method of embodiments, support structure patterns may be formed based on the correction values for the target full shot data. For example, in at least one example, the pattern correction device 1 may be applied in a control module configured to direct a circuit processing apparatus to produce, based on the correction values, the first and second support structure patterns 130 and 140 to compensate for, e.g., the torque, deflection, external forces, and/or the like. For example, in at least one embodiment, the circuit processing apparatus may be configured to adjust the position of a stage on which the first and second support structure patterns 130 and 140 are being produced based on the correction values. Additionally, in at least one embodiment, the pattern correction device 1 may be configured to pause production when the correction values are greater than a tolerance threshold. For example, in at least one example, a change detected in the circuit processing apparatus may be applied, in real-time, to the pattern correction device 1, and the viability of the circuit being processed can be estimated, and if the likelihood of viability is below a threshold (and/or the correction values are greater than a tolerance threshold) the circuit processing apparatus may be paused and/or the circuit may be discarded and/or reprocessed.

Because the target full shot data reflects pattern leaning of the lower electrodes 120, support structure patterns may be formed to address pattern leaning of the lower electrodes 120.

As described above, according to the one or more of the above embodiments, the pattern correction device and method may accurately predict leaning of a plurality of lower electrodes by calculating a deformation coefficient based on a cantilever beam analysis method and removing outliers. Owing to the prediction of pattern leaning of the lower electrodes, support structure patterns may be precisely formed for the lower electrodes, and thus the stability of semiconductor devices may be improved.

While the inventive concepts have been particularly shown and described with reference to embodiments thereof, it will be understood that various changes in form and details may be made therein without departing from the spirit and scope of the following claims.

What is claimed is:

1. A pattern correction method comprising:
acquiring, from a database, full shot data comprising full shot data coordinates and a misalignment value;
determining a deformation coefficient of the full shot data based on a cantilever beam analysis with respect to the full shot data;
extracting first-coordinate data along a first axis in a bit line direction and second-coordinate data along a second axis in a word line direction based on the full shot data;
classifying the full shot data based on the extracted first-coordinate data and the extracted second-coordinate data;
removing outliers from the full shot data;
training a pattern prediction model to predict misalignment values based on the first-coordinate data and the second-coordinate data by setting a predicted misalignment value as an output value, and setting the first-coordinate data, the second-coordinate data, the misalignment value, and the deformation coefficient of the full shot data as input values;
acquiring target full shot data from the database;
extracting a feature vector from the target full shot data using the pattern prediction model with respect to the target full shot data;
detecting a target misalignment value of the target full shot data based on the feature vector; and
determining a correction value for the target full shot data based on the predicted misalignment value of the target full shot data.

2. The pattern correction method of claim 1, wherein the determining the deformation coefficient is based on at least one of a load acting on a lower electrode, a reaction force of a first support structure pattern, and a reaction force of a second support structure pattern.

3. The pattern correction method of claim 2, wherein
the determining the deformation coefficient comprises setting the deformation coefficient to be 1 for a main unit block, and
the deformation coefficient is determined for each of a plurality of unit blocks based on a ratio of the reaction force of the first support structure pattern and the reaction force of the second support structure pattern.

4. The pattern correction method of claim 1, wherein the classifying of the full shot data is based on a differential value of the first-coordinate data and a differential value of the second-coordinate data.

5. The pattern correction method of claim 4, wherein the classifying of the full shot data comprises identifying a plurality of shot regions based on the differential value of the first-coordinate data and the differential value of the second-coordinate data.

6. The pattern correction method of claim 1, wherein the removing of the outliers from the full shot data is based on an isolation forest algorithm.

7. The pattern correction method of claim 1, wherein the classifying of the full shot data based on the first-coordinate data and the second-coordinate data and the removing of the outliers from the full shot data are performed simultaneously and in parallel.

8. The pattern correction method of claim 1, wherein the deformation coefficient comprises
a first deformation coefficient with respect to the first axis in the bit line direction, and
a second deformation coefficient with respect to the second axis in the word line direction.

9. The pattern correction method of claim 8, wherein
the removing of the outliers from the full shot data comprises classifying the full shot data into a first data set with respect to the first axis and a second data set with respect to the second axis after removing the outliers from the full shot data,
the first data set comprises the first-coordinate data, the second-coordinate data, the first deformation coefficient, and a first misalignment value for the first axis, and
the second data set comprises the first-coordinate data, the second-coordinate data, the second deformation coefficient, and a second misalignment value for the second axis.

10. The pattern correction method of claim 1, wherein the training of the pattern prediction model is based on a regression learning method using a Gaussian process.

11. A pattern correction method comprising:
acquiring, from a database, full shot data comprising full shot coordinates and a misalignment value;
determining a deformation coefficient of the full shot data based on a cantilever beam analysis with respect to the full shot data;
extracting first-coordinate data along a first axis in a bit line direction and second-coordinate data along a second axis in a word line direction based on the full shot data;
classifying the full shot data based on the extracted first-coordinate data and the extracted second-coordinate data;
removing outliers from the full shot data;
training a pattern prediction model to predict misalignment values based on the first-coordinate data and the second-coordinate data, the training based on regression learning using a Gaussian process and includes setting a predicted misalignment value as an output value, and setting the first-coordinate data, the second-coordinate data, the misalignment value, and the deformation coefficient of the full shot data as input values;
acquiring target full shot data from the database;
extracting a feature vector from the target full shot data using the pattern prediction model with respect to the target full shot data;
detecting a target misalignment value of the target full shot data based on the feature vector; and
determining a correction value for the full shot data based on the target misalignment value,
wherein the deformation coefficient comprises a first deformation coefficient with respect to the first axis in the bit line direction and a second deformation coefficient with respect to the second axis in the word line direction.

12. The pattern correction method of claim 11, wherein the removing of the outliers from the full shot data comprises
removing the outliers from the full shot data based on an isolation forest algorithm, and
classifying the full shot data into a first data set with respect to the first axis and a second data set with respect to the second axis after removing the outliers from the full shot data,
wherein the first data set comprises the first-coordinate data, the second-coordinate data, the first deformation coefficient, and a first misalignment value for the first axis, and
the second data set comprises the first-coordinate data, the second-coordinate data, the second deformation coefficient, and a second misalignment value for the second axis.

13. The pattern correction method of claim 11, wherein the determining the deformation coefficient of the full shot data comprises
determining a ratio between a lower electrode, a first support structure pattern, and a second support structure pattern based on a load acting on the lower electrode, a reaction force of the first support structure pattern, and a reaction force of the second support structure pattern; and
determining the deformation coefficient for each of a plurality of unit blocks based on the ratio.

14. The pattern correction method of claim 13, wherein the determining of the deformation coefficient comprises setting the deformation coefficient to be 1 for a main unit block,
wherein the deformation coefficient is determined for each of the plurality of unit blocks based on a ratio of the reaction force of the first support structure pattern and the reaction force of the second support structure pattern.

15. The pattern correction method of claim 11, wherein the classifying of the full shot data is based on a differential value of the first-coordinate data and a differential value of the second-coordinate data,
wherein the differential value of the first-coordinate data is determined based on
$$f {X}_{i + 1} - f {X}_{i} = d {X}_{i}$$
where fXᵢ₊₁ refers to an (i+1)th first-coordinate data value, fXᵢ refers to an ith first-coordinate data value, dXᵢ refers to a differential value of the ith first-coordinate data value, and i refers to a natural number ranging from 1 to n.

16. The pattern correction method of claim 11, wherein the classifying of the full shot data comprises
classifying the full shot data in units of shots and chips with respect to the first axis based on the first-coordinate data and the second-coordinate data, and
classifying the full shot data in units of shots and chips with respect to the second axis based on the first-coordinate data and the second-coordinate data.

17. The pattern correction method of claim 10, wherein the pattern prediction model classifies the target full shot data in units of shots and chips based on the classified full shot data.

18. A pattern correction method comprising:
acquiring, from a database, full shot data comprising full shot coordinates and a misalignment value;
determining a deformation coefficient of the full shot data based on a cantilever beam analysis method with respect to the full shot data;
extracting first-coordinate data along a first axis in a bit line direction and second-coordinate data along a second axis in a word line direction based on the full shot data;
classifying the full shot data based on the extracted first-coordinate data and the extracted second-coordinate data;
removing outliers from the full shot data;
training a pattern prediction model to predict misalignment values based on the first-coordinate data and the second-coordinate data, the training based on regression learning using a Gaussian process and includes setting a predicted misalignment value as an output value, and setting the first-coordinate data, the second-coordinate data, the misalignment value, and the deformation coefficient of the full shot data as input values;
acquiring target full shot data from the database;
extracting a feature vector from the target full shot data using the pattern prediction model with respect to the target full shot data;
detecting a target misalignment value of the target full shot data based on the feature vector; and
calculating a correction value for the full shot data based on the target misalignment value,
wherein the determining the deformation coefficient of the full shot data comprises determining a ratio between a lower electrode, a first support structure pattern, and a second support structure pattern based on a load acting on the lower electrode, a reaction force of the first support structure pattern, and a reaction force of the second support structure pattern, and
determining the deformation coefficient for each of a plurality of unit blocks based on the ratio,
wherein the deformation coefficient comprises a first deformation coefficient with respect to the first axis in the bit line direction and a second deformation coefficient with respect to the second axis in the word line direction.

19. The pattern correction method of claim 18, wherein the classifying of the full shot data comprises
classifying the full shot data based on a differential value of the first-coordinate data and a differential value of the second-coordinate data,
classifying the full shot data in units of shots and chips with respect to the first axis based on the differential value of the first-coordinate data and the differential value of the second-coordinate data, and
classifying the full shot data in units of shots and chips with respect to the second axis based on the differential value of the first-coordinate data and the differential value of the second-coordinate data,
wherein the differential value of the first-coordinate data is calculated based on
$$f {X}_{i + 1} - f {X}_{i} = d {X}_{i}$$
where fXᵢ₊₁ refers to an (i+1)th first-coordinate data value, fXᵢ refers to an ith first-coordinate data value, and dXᵢ refers to a differential value of the ith first-coordinate data value.

20. The pattern correction method of claim 18, wherein the deformation coefficient has different values according to sizes of the plurality of unit blocks.
